(19) United States
(12) Patent Application Publication
(10) Pub. No.: US 2004/0251958 A1
(43) Pub. Date: Dec. 16, 2004

(54) Active filter

(76) Inventor: Peter Paakonen, Stockholm (SE)

Correspondence Address: NIXON & VANDERHYE, PC, 1100 N GLEBE ROAD, 8TH FLOOR, ARLINGTON, VA, 22201-4714, US

(21) Appl. No.: 10/481,251

(22) PCT Filed: Jun. 18, 2002
(86) PCT No.: PCT/SE02/01199

(30) Foreign Application Priority Data
Jun. 18, 2001 (SE) 0102151.8

(51) Int. Cl. H03B 1/00

(52) U.S. Cl. 327/552

(57) ABSTRACT

The present invention relates to an active filter for suppressing noise and inter-modulation. The filter has at least one impedance circuitry such as at least one resonator and/or at least one reactive component. A feedback loop comprising amplifier means and lines connected to it compensates for the power losses provided in the circuitry and making the filter active. At least one coupler means is provided, each as an interface between the amplifier means and the impedance circuitry. Each coupler has an impedance termination.

### TECHNICAL FIELD

This invention relates to an active filter of the kind disclosed in the preamble of claim 1, and especially to the connection in relation to resonators or reactive components in an active filter. The invention relates to a band-stop, a band-pass, a low-pass and a high-pass filters and the connection in relation to their resonators or reactive components.

### BACKGROUND

The invention is particularly related to be used in base stations for serving mobile telephones, but it is not limited to that particular technical field. The same problem, as described below, also relates to sending and receiving radio programs. At present disturbing devices in some systems connected to antennas send signals, which lie near to the wavelength band allotted to send and/or receive signals of a particular radio transceiver. Therefore, the transceiver(s) needs band filters having a very high selectivity. This in turn demands band filters having very high Q-values. There is also a need for high pass and low pass filters having very steep frequency limits. This invention intends to provide an active filter of the kind mentioned above.

In conventional passive filters the Q-value is increasing with increasing size of the resonator or resonators, and consequently with increasing filter size. Since the space is an important factor in the radio frequency communication systems of today, one strives to develop filters with increasing Q-values in alternative ways.

A problem with active filters is that they generate noise and inter-modulation. Since passive filters don't generate noise and only generate a very modest level of passive inter-modulation, which is most of the times negligible, requirements on active filters shouldn't be any different. Otherwise one kind of performance has been traded off for another type of performance still leaving an undesired result. Many different active filter circuits have been introduced, but only a few have low noise and inter-modulation levels. The difficulty lies in the design of the feedback loop, which has to provide among other things a good match towards the amplifier, an accurate phase-delay, a well-defined gain and preferably no contribution to noise and inter-modulation. All of these parameters in many cases being functions of each other make the design of the feedback loop quite difficult.

### RELATED ART

Nowadays air cavities and/or big resonators are often used in band filters in order to provide a high Q-value. This leads to bulky space demanding filters, which often are heavy and also expensive. As an alternative smaller filters can be constructed by means of resonators having another dielectric than air in the cavities.

Active filters provide an alternative way to increase the Q-values of the resonators without renouncing the size of the filter. Unfortunately, the active filter has a disadvantage, which is caused of the same part giving it advantages, i.e. the amplifier. The amplifier, which often is provided in some form of a feedback loop in the active filter, causes inter-modulation and noise. This must be taken into consideration, otherwise the inter-modulation and noise will propagate to the output of the filter resulting in poor performances.

A prior art active band-stop filter is illustrated in FIG. 1. It comprises a T-connection connected to a transmission line TL in order to drain out a frequency band from the signal on the line TL. A resonator RES is connected to the middle arm of the T-connection through a capacitance coupling CP1. The resonator is connected to earth. A feedback loop for the filter is connected to the connection between the capacitance coupling CP1 and the resonator RES. This device comprises an amplifier circuit AMP so configured as to become a negative resistance in an operation band of the band-stop filter. The amplifier circuit is connected through a capacitance coupling CP3, a phase adjuster illustrated by a delaying means PH, which is provided by an adjusted length of the connector to an amplifier AMP and a capacitance coupling CP2 coupled to the resonator RES. This kind of filter is shown in U.S. Pat. No. 5,291,160.

When two relatively large signals combine in a non-linear stage and happen to produce one or more new frequencies, the result is called inter-modulation distortion (IMD). Inter-modulation distortion is extremely important to minimise in radio systems. When non-linearities exist in amplifiers, mixers, and filter, distortion products are generated. If a signal tone is transmitted in band, only harmonics are generated, which in the case of IF frequencies are out-of band and easily attenuated. If two or more tones are transmitted, in-band IMD products are created around the transmitted tones. These tones may be desired signals, undesired signals, or a combination of both.

The electrical performance of a system can be affected by many factors, but the effect of noise is probably one of the most fundamental. Noise power is a result of random processes, such as the flow of charges or holes in an electron tube or solid-state device, propagation through the ionosphere or other ionised gas, or, most basic of all, the thermal vibrations in any component at a temperature above absolute zero. Noise can be passed into a system from external sources, or generated within the system itself. In either case the noise level of a system sets the lower limit on the strength of a signal that can be detected in the presence of the noise. Thus, it is generally desired to minimise the residual noise level of a radar or communications receiver, to achieve the best performance. In some cases, such as radiometers or radio astronomy systems, the desired signal is actually the noise power received by an antenna, and it is necessary to distinguish between the received noise power and the undesired noise generated by the receiver system itself.

The key difference between circuit theory for low frequency and transmission line theory for radio frequency or microwave is the electrical size. Circuit analysis assumes that the physical dimensions of a network are much smaller than the electrical wavelength, while transmission lines may be a considerable fraction of a wavelength, or many wavelengths, in size. Thus a transmission line is a distributed parameter network, where voltages and currents can vary in magnitude and phase over its length. A transmission line is often schematically represented as a two-wire line, since transmission line (for TEM wave propagation) always have at least two conductors.

An active-type band-pass filter for use in a mobile communication system is described in U.S. Pat. No. 5,379,009. The filter has a compact structure and a minimum noise figure by setting a coupling Q-factor on an input side of an amplifier, a coupling Q-factor on an output side of the amplifier, and a gain G of the amplifier so that they satisfy the condition that Qₑ₁<Qₑ₂ and 1/Qₑ₁=G/Qₑ₂. The total no-load Q-factor is set in the negative region. In this way a reduced noise figure can be attained. However, the matching is only possible for a limited frequency range and does therefore not provide the best possible environment for the amplifier.

### THE INVENTION

An object of the invention is to provide an active filter having small size and little noise and small inter-modulation with signals from neighbouring transmitter channels.

Another object of the invention is to provide an active filter, in which as small amount as possible of possible noise and inter-modulation propagates to the output of the filter.

Still another object of the invention is to provide a band pass filter having at least one resonator and/or reactive component and having steep limit frequencies.

Yet another object of the invention is to provide a band-stop filter having at least one resonator and/or reactive component and having steep limit frequencies.

Still another object of the invention is to provide a low pass filter having at least one resonator and/or reactive component and having a steep limit frequency.

Yet another object of the invention is to provide an active high pass filter having at least one resonator and/or reactive component and having a steep limit frequency.

Still another object of the invention is to provide an active filter presenting a good stability.

Yet another object of the invention is to provide an active filter with an improved Q-value and an improved stability in relation to prior art active filters.

Still another object of the invention is to provide an active filter with an improved Q-value and an improved stability in relation to prior art active filters, for frequencies outside the working frequency.

These and other objects are fulfilled by an active filter having the features disclosed in the characterising part of claim 1. Further developments and features of the invention are disclosed in the rest of the claims.

The present invention relates to an active filter for suppressing noise and inter-modulation having at least one impedance circuitry, such as at least one resonator and/or at least one reactive component, a feedback loop comprising amplifier means in order to compensate for the power losses provided in the circuitry and making the filter active, and lines connected to the amplifier. The invention is characterized by comprising:

at least one coupler means, each provided as an interface between the amplifier means and the impedance circuitry; and

an impedance termination for each coupler.

At least one of the coupler means is located externally of the impedance circuit.

The active filter has preferably a determined coupling factor between the coupler means and the impedance circuitry dependent on amplifier characteristics and circuitry losses. The determined coupling factor could then obtain an optimum regarding Q-value, noise suppression and inter-modulation suppression.

The active filter could have phase adjusting means, provided by at least one of the following elements: the lines, the amplifier means, the coupler means, the impedance circuitry, or a combination of at least two of the elements stated above. The impedance termination could be either resistive or reactive, or a combination of both. The amplifier means could comprise at least one, preferably more, amplifiers, which then are parallel connected, or an amplifier having at least one, preferably more, outputs and/or inputs, or a combination of both. The amplifier means and an impedance given by the lines, the coupler means and its impedance termination are preferably matched against each other. The matching is then provided in dependence of one of the following features: noise, power, gain, or a combination of at least two of the features mentioned above.

One port [one of the input(s) or output(s)] of each amplifier means could be connected directly to the impedance circuitry; and another port [one of the output(s) or input(s)] of each amplifier means could be connected to the impedance circuitry through the coupler means. A first port (the input/output) of the amplifier means and the impedance given by the lines, the coupler means and its impedance termination are preferably matched against each other; and a second port (the output/input) of the amplifier means and the impedance given by the lines and the impedance circuitry are matched against each other. The matching is preferably provided in dependence of one of the following features: noise, power, gain, or a combination of at least two of the features mentioned above.

At least one of the input(s) and/or at least one of the output(s) of the amplifier means could be connected to the impedance circuitry through an individual one of the coupler means. The amplifier means could be connected in either direction in the feedback loop. The impedance circuitry could be connected either parallel or in series to the main transmission line. The active filter could be a low pass filter, a high pass filter, a band pass filter, or a band-stop filter. The active filter could comprise multiple filter elements provided in series, parallel, or in combinations of series and parallel combinations.

Thus, there are at least one amplifier or an amplifier coupled to a resonator, the amplifier or amplifiers having at least one output. It is to be noted that for amplifiers having several outputs the different outputs of the amplifiers most often have at least slightly different phases.

The noise and inter-modulation is suppressed by means of coupler or couplers connected to an impedance circuitry, such as resonators and/or reactive components. Each coupler is provided with impedance termination. The coupler or couplers represents the interface or a part of the interface between the impedance circuitry and the amplifier. It is a fact that total elimination of noise is impossible.

However, if then one of the ports (input or output) of the amplifier or amplifiers is connected to the active impedance circuitry Z, such as a resonator or reactive component, the couple rate must be adjusted in the active impedance circuitry. The function is the same as with a coupler. A disadvantage of replacing the coupler by a connection directly into the impedance circuitry Z could be that the amplifier then could have inferior performances due to bad adaptation.

The resonator could be of almost any kind, such as transmission line resonator, dielectric resonator, rectangular wave-guide resonator, circular wave-guide resonator, etc.

The reactive component could be an inductance, or a capacitance, or could be more complex.

The amplifier can be coupled loose or hard in against the impedance circuitry. Using a hard connection for a band filter a maximal Q-value could be attained at least as far as the feedback structure does not come into self-oscillation. Simultaneously, the suppression of the noise and the inter-modulation is very low. A loosely coupled amplifier does not give the same contribution to the Q-value. However, it suppresses the noise and the inter-modulation in a better way.

By adjusting the coupling factor, the gain, the matching, and the phase in the feedback loop right an optimum can be obtained regarding Q-value, noise suppression, and inter-modulation suppression. The active filter can then obtain a considerably higher Q-value than a passive filter of the same size, without impair as to the performances. Several filters could advantageously be connected in cascade or parallel. This could give a broader pass-band or stop-band for the band filters and still have steep frequency limits.

It is also to be noted that if one coupler is provided to an output each of several outputs of an amplifier, or, if several amplifiers are provided, one coupler is provided to each amplifier output for a particular filter, then the Q-value of the filter will increase even further. The increase of the Q-value becomes however less for each amplifier or amplifier output added, setting up a balance between the increase of performance in the filter and the space and energy consumption.

Another benefit of using several amplifiers or amplifier outputs is the phase stability. Temperature and other factors tend to shift the phase of the feedback loop making the performance of the filter unstable. This may for instance manifest as jitter at the depth of a band-stop filter. If the phase of the different amplifiers or amplifier outputs is slightly different in each amplifier or amplifier output, a phase-compensation is achieved.

### ADVANTAGES

There are prior art solutions, in which the amplifier is connected in against the resonator in other ways than with directional couplers. One of these ways is illustrated in U.S. Pat. No. 5,379,009 mentioned above. However, no or few of the prior art methods could manage the prescribed noise and inter-modulation performances. Prior art active filters have not either any coupler with impedance termination making them stable.

The advantages of using couplers compared to other methods are:

The degree of coupling can be varied arbitrarily.

The coupler provides the possibility to make an amplifier, which is matched against the impedance of the coupler and the termination.

### BRIEF DESCRIPTION OF THE DRAWINGS

For a more complete understanding of the present invention and for further objects and advantages thereof, reference is now made to the following description of examples of embodiments thereof—as shown in the accompanying drawings, in which:

FIG. 1 illustrates a prior art system for a band-stop filter;

FIG. 2 illustrates a simplified schematic of a receiver circuit between the antenna and a detector to detect the informative part of the antenna signal;

FIG. 3 illustrates a basic coupling of a parallel-coupled active filter according to the invention;

FIG. 4 shows a filter circuit according to prior art;

FIG. 5 shows a Smith diagram;

FIG. 6 shows a filter circuit corresponding to the filter in FIG. 3;

FIG. 7 shows a Smith diagram;

FIGS. 8 to 11 illustrate different embodiments of the coupling shown in FIG. 3;

FIG. 12 illustrates a basic coupling of a serial-coupled active filter according to the invention;

FIGS. 13 to 15 illustrate different embodiments of the coupling shown in FIG. 12;

FIGS. 16 to 23 illustrate more embodiments of active filters according to the invention; and

FIG. 24 illustrates an example of a combination of different filters.

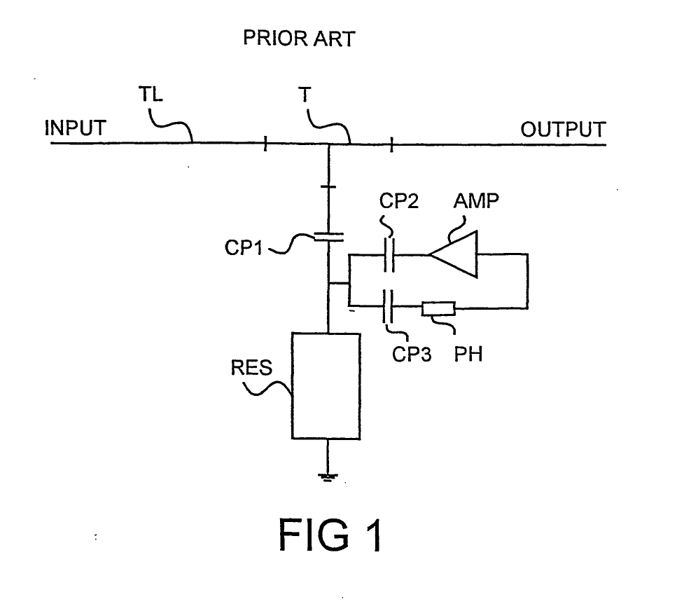

### DETAIL DESCRIPTION OF EMBODIMENTS

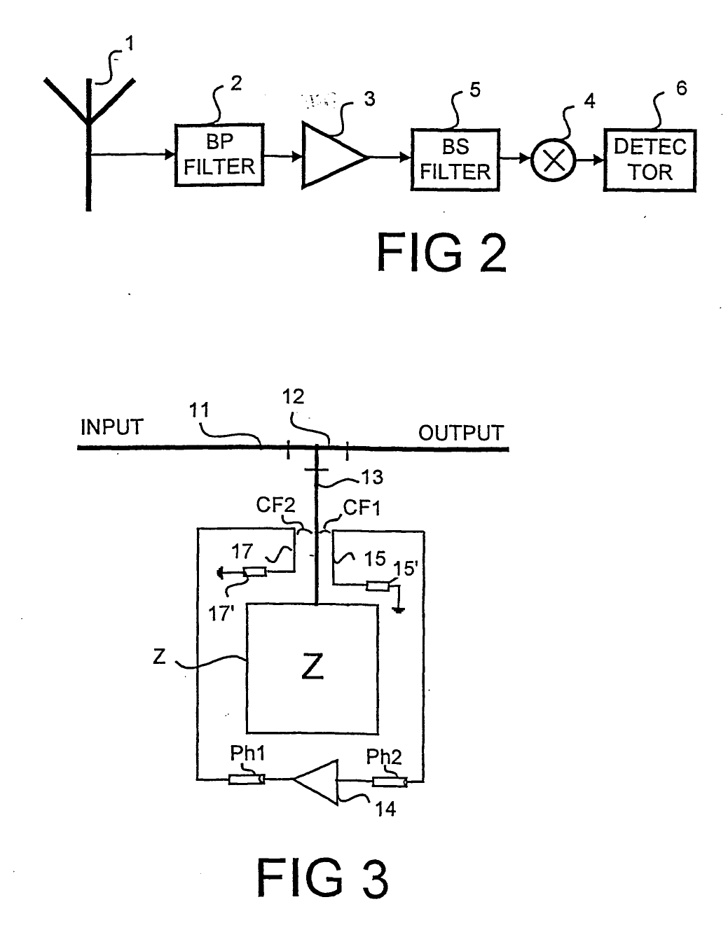

FIG. 2 illustrates schematically a simplified schematic of a typical circuit of a receiver system in order to give an example of a use of an active filter according to the invention. The signal from an antenna 1 is connected to a band pass filter 2, in turn connected to an amplifier 3. The band pass filter protects the amplifier 3 from high signals outside the pass band of the filter 2. However, not wanted signal parts are still left in the pass band. The signal parts not wanted will cause trouble in the rest of the circuit, particularly in a mixer 4, in which the demodulation of the signal before sending it to a detector 6 is provided. Therefore, a band-stop filter 5 having the features according to the invention could be provided between the amplifier 3 and the mixer 4 in order to filter out the troublesome signal parts. Since these signal parts often are situated very near to the wanted signal band a band-stop filters having very steep frequency limits is demanded.

However, the use of the invention is not limited to a band-stop filter, as described above. The invention relates to all kinds of active filters. The active basic filter could thus be a low pass filter, a high pass filter, a band pass filter, or a band-stop filter.

Generally, active filters are often implemented by means of resonators or reactive components. The filter characteristics are therefore determined by these resonators or reactive components. Demands on a filter are approximately the same as demands on the resonators or the reactive components.

Even though embodiments of one segment of an active filter are described below in relation to the FIGS. 3 to 23 regarding the embodiments of the invention, it is to be noted that this active filter often is a part of a filter construction having a number of segments. These segments could be cascaded or parallel connected, or a combination of both as is apparent from FIG. 24.

In the embodiment shown in FIG. 3, which is the preferred one and which is a basic filter illustrating parallel connection of the filter, an impedance circuitry Z is connected to a main transmission line 11 with a junction unit, for example by means of a T-connection 12. A transmission line 13 is connected to the junction unit, i.e. the centre arm of the T-connection 12 in the embodiment shown. The transmission line 13 is connected between the middle arm of the T-connection 12 and the impedance circuitry Z.

A feedback loop comprising an amplifier 14 and the lines connected to it has its input connected to a coupler 15 having an impedance termination 15′, in turn connected to earth and its output to another coupler 17 also having an impedance termination 17′ connected to earth. The termination gives stability to the filter circuitry, i.e. it will not be particularly sensitive to the surroundings. It is, however, a fact that total elimination of noise is impossible. The amplifier comprises phase adjusters provided by its connection lines Ph1, Ph2. The impedance termination of each coupler could either be resistive, which is to be preferred, or reactive, or a combination of both. Each coupler is provided as an interface between the amplifier and the impedance circuitry Z. There is thus a determined coupling factor, CF1 for the coupler 15 and CF2 for the coupler 17, between each coupler and the impedance circuitry Z in dependence on the amplifier characteristics and the circuitry losses. The determined coupling factor is adapted to obtain an optimum regarding Q-value, noise suppression and inter-modulation suppression. The coupling factor for a coupler and its qualities has the same purpose in all the embodiments described below.

The amplifier 14 and an impedance given by the lines Ph1, Ph2, the couplers 15, 17 and their impedance terminals 15′, 17′ are matched against each other. The matching could be provided in dependence of noise, or power, or amplifier gain or different combinations (at least two) of these features.

A coupler is a passive component used for power division or power combining. Couplers can be built with very low loss (through the main arm) and good directivity, if it is a directional coupler.

Directional couplers are preferred in that they are directional, have low loss, and high reverse isolation. Ideally, a signal travelling in the reverse direction of the coupler will not appear at all at the coupled port, since its energy is absorbed in the internal termination of the coupler.

The phase can be adjusted by amending either one of the lines Ph1, Ph2 between the amplifier and the couplers, or the amplifier, or one of the couplers, or the impedance circuitry Z, or a combination of at least two of the elements stated above.

The couplers 15 and 17 bring about that it is possible to adjust the coupling factor. A certain coupling factor is provided between the couplers and impedance circuitry Z dependent on the amplifier characteristics, such as gain and/or phase, and circuitry (resonator) losses.

Additionally, in prior art active filters, the impedance as seen from the input and output of the amplifier is not constant but varies with frequency. Also, the impedance may vary when other parameters of the circuit are tuned. This makes it difficult to find the optimum performance of the circuit. In present innovation the couplers and the coupler terminations guarantee a stable environment for the amplifier.

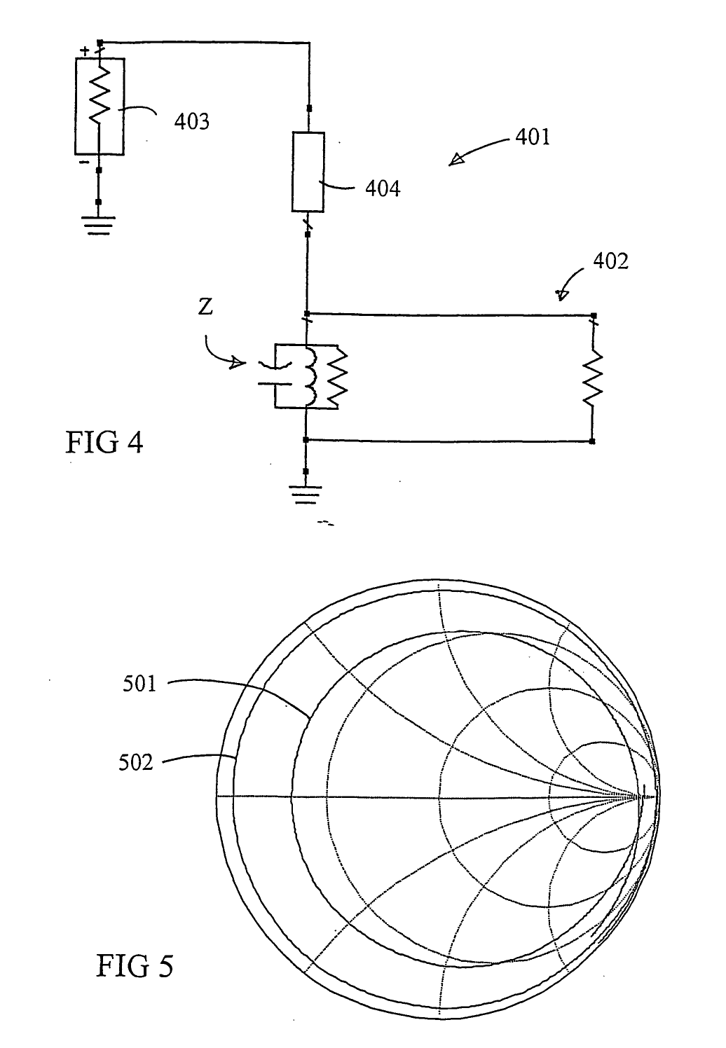

With the aid of FIGS. 4-7 advantages of the present invention will be explained further.

In many prior art designs of filters, negative resistance circuits are implemented to enhance the unloaded Q-value of the resonator. FIG. 4 shows a circuit 401 according to prior art, with a 50 ohm generator 403 and a transmission line 404 having a length corresponding to ¼of a wavelength at the working frequency of the circuit. A negative resistance 402 is applied to the circuit. The negative resistance 402 is connected to a resonator Z, also referred to as an impedance circuitry. As is known to the person skilled in the art, the negative resistance could be implemented with a transistor circuit, and the connection to the resonator could be done in a number different ways.

FIG. 5 shows a Smith diagram with a first reflection circle 501, depicting a reflection response as seen from a generator in a circuit with a resonator as the one of the circuit in FIG. 4, but with no negative resistance. A second reflection circle 502 depicts a reflection response as seen from the generator 403 of the circuit 401 in FIG. 4. It can be seen in FIG. 5 that the second reflection circle 502 is larger than the first reflection circle 501 for all frequencies.

Thus, for increased negative resistance of the circuit, the reflection circle is expanded at all frequencies. The losses for all frequencies, including the working frequency, are thus decreased. However, the stability also decreases for all frequencies as the negative resistance is increased. For frequencies where the circuit is already close to instability this could be critical. To keep the circuit stable one might have to settle for a non optimum Q-value. Compensation is of course possible but this increases the complexity of the circuit and is not always easy to implement. Usually inherent bad performance can not be corrected without losses in other performance.

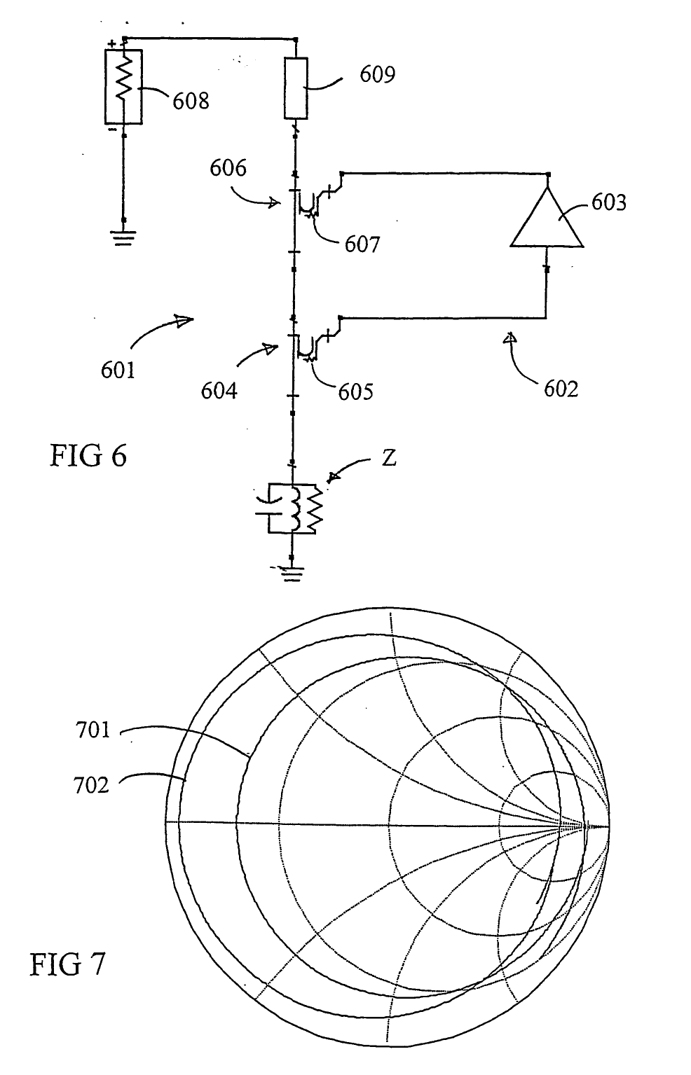

The present invention claims not only to improve the Q-value of the circuit but also to improve the stability for frequencies outside the working frequency. FIG. 6 shows a circuit 601 corresponding to the preferred embodiment of the invention, depicted in FIG. 3, having a 50 ohm generator 608 and a transmission line 609 having a length corresponding to ¼ of a wavelength at the working frequency of the circuit. A feedback loop 602 comprises an amplifier 603 and the lines connected to it has its input connected to a coupler 604 having an impedance termination 605, in turn connected to earth and its output to another coupler 606 also having an impedance termination 607 connected to earth. Each coupler is provided as an interface between the amplifier and an impedance circuitry Z, corresponding to the impedance circuitry Z of circuit in FIG. 4. The couplers are directed in the same direction, in relation to the connection to the impedance circuitry Z. The couplers are directed as can be seen in FIG. 3.

FIG. 7 shows, for a range of frequencies from 600 MHz, to 1,25 GHz, a Smith diagram with a third reflection circle 701, depicting a reflection response as seen from a generator in a circuit with a resonator as the one of the circuit in FIG. 6, but with no feedback loop. A fourth reflection circle 702 depicts a reflection response as seen from the generator 608 of the circuit 601 in FIG. 6. It can be seen in FIG. 7 that the forth reflection circle 702 is moved, in relation to the third reflection circle 701, to the left in the diagram, which is a direction where the losses are decreased for the desired working frequency. It should also be noted that the forth reflection circle 702 is not considerably larger than the third reflection circle 701. The Q-value can therefore be enhanced for the working frequency while the stability of the circuit never becomes critical for other frequencies.

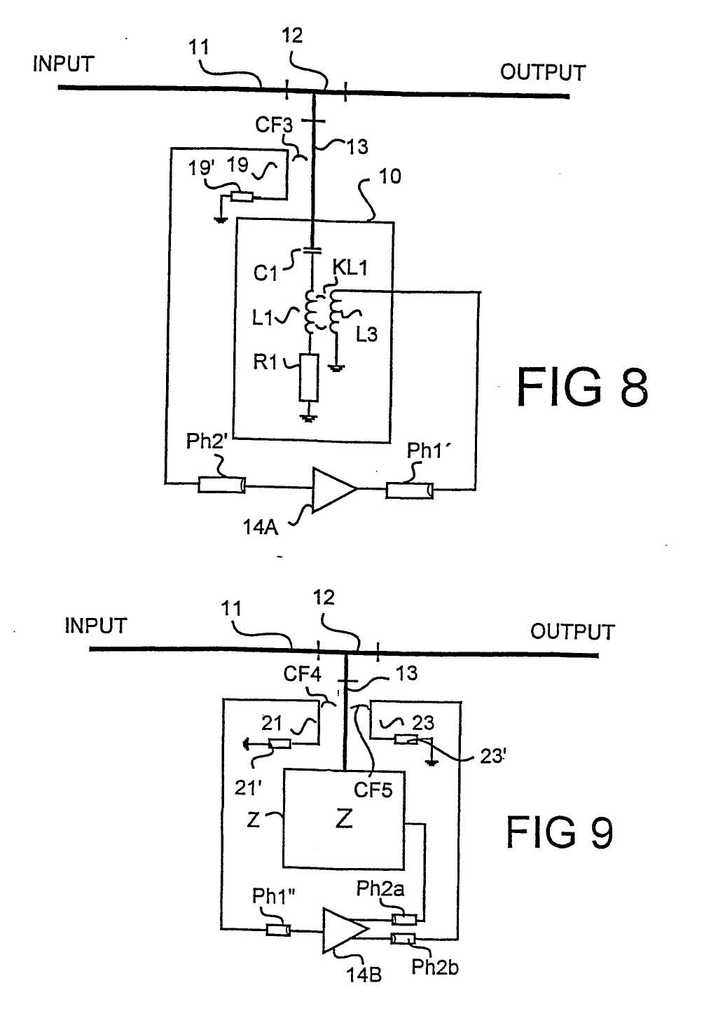

As apparent from FIG. 8, which is an example of the parallel connected filter in FIG. 3, and in which a particular impedance circuitry 10 is shown as an illustration of a kind of circuitry to be used, the active filter according to the invention need only have one of its input and output interface in the form of a coupler. As in all the embodiments the amplifier comprises phase adjusters provided by its connection lines Ph1′, Ph2′. The amplifier input is connected to a coupler 19 provided with a termination 19′ and having a coupling factor CF3. Its output is connected to the inside of the impedance circuitry 10, which in this embodiment is a resonator. As illustrated in FIG. 8, the line 13 is inside of the resonator connected to a capacitance C1, an inductance L1 and a resistance R1 in series having its other end connected to earth. The output of the amplifier is connected to an inductance L3 coupled to the inductance L1 by a coupling factor KL1.

It is to be noted that the elements inside the resonator are illustrative only, and that these elements in reality are provided in the way common within the technique. How they are seated and formed inside the resonator housing is not a part of the invention, is commonly known by the persons skilled in the art, and is therefore not described in detail whether for this embodiment or for any of the others.

In the embodiment shown in FIG. 9, which also is an exemplification of the filter shown in FIG. 3, the impedance circuitry Z could be either a resonator or a reactive component. This embodiment illustrates that an amplifier 14B having one input and two outputs could have the input connected to a coupler 21 having a coupling factor CF4 and a termination 21′ to earth, one output connected to another coupler 23 having a coupling factor CF5 and a termination 23′ to earth, and the other output connected to the inside of the impedance circuitry Z. The amplifier comprises phase adjusters provided by its connection lines Ph1″, Ph2a and Ph2b.

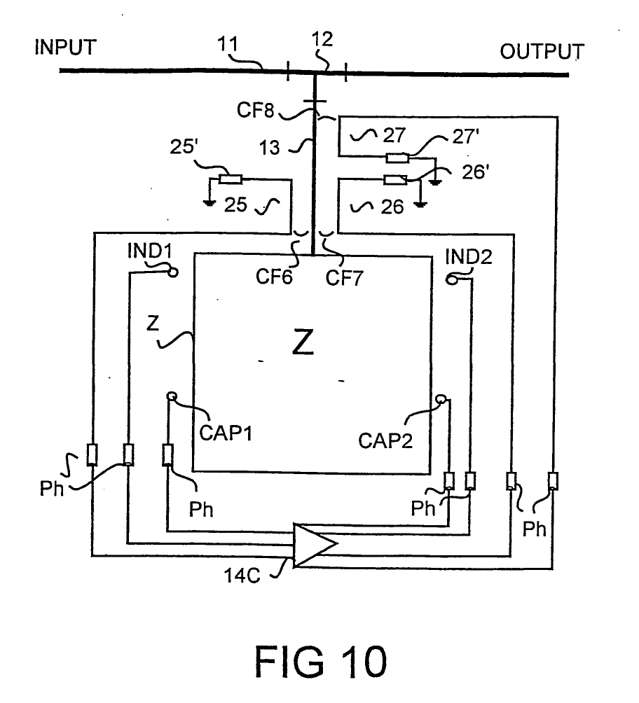

In the embodiment shown in FIG. 10, which also is an exemplification of the basic filter shown in FIG. 3, an embodiment is shown, in which a lot of combinations could be done. The amplifier 14C comprises several inputs and outputs, each connected to a separate one of several terminated couplers 25, 26, 27 and to inside component the impedance circuitry Z. Like for all the embodiments the amplifier 14C has its lines Ph connected to all its inputs and outputs functioning as individual phase adjusters, and thus its phase adjusting could be provided by for example changing the length of at least one of its lines.

A certain coupling factor is provided between the couplers and impedance circuitry Z dependent on the amplifier characteristics, such as gain and/or phase, and circuitry (resonator) losses.

The amplifier 14C is suitably provided with a number of inputs, for example three, and/or outputs, for example four, as in this embodiment. This kind of amplifier is common within the technical field. The inputs and outputs often have different phases provided by the different phase adjusters, provided by different line lengths Ph from/to the actual amplifier unit to the different inputs/outputs. The inputs and the outputs from the amplifier to the impedance circuitry Z could be alternative with one another, or at least some of them could be used simultaneously.

The couplers 26 and 27 are turned in different directions. This illustrates that it is possible to choose one or the other of the directions for the inventive filter. It depends on the turning of the couplers. The coupler 25 could be turned in the other direction than what is shown.

However, according to the invention, at least one of the terminals of the amplifier 14C must be connected to a coupler, independently if the coupler 25, 26, 27 is chosen for this purpose, since a coupler is terminated by a termination 25′, 26′ and 27′, respectively. A certain coupling factor CF6, CF7, CF8 is provided between the couplers 25, 26, and 27, respectively, and the impedance circuitry Z dependent on the amplifier characteristics, such as gain and/or phase, and circuitry (resonator) losses. The terminations 25′, 26′ and 27′ for the couplers 25, 26, and 27, respectively, could be chosen arbitrarily, but a termination used very often for couplers is 50 ohm.

The coupler 26 is provided near to the impedance circuitry Z. The other coupler 27 is provided more near to the T-connection 12. This is just an alternative way to place the coupler.

However, if then one of the ports (input or output) of the amplifier or amplifiers is connected to the active impedance circuitry Z, such as a resonator or reactive component, the couple rate must be adjusted in the active impedance circuitry. The function is the same as with a coupler. A disadvantage of replacing the coupler by a connection directly into the impedance circuitry Z could be that the amplifier then could have inferior performances due to bad adaptation.

A more stable filter characteristic is obtained by the use of several amplifiers. However, this causes a higher energy consumption than with only one amplifier and a larger space due to the extra amplifiers. Instead of extra amplifiers a single amplifier having several outputs could be used.

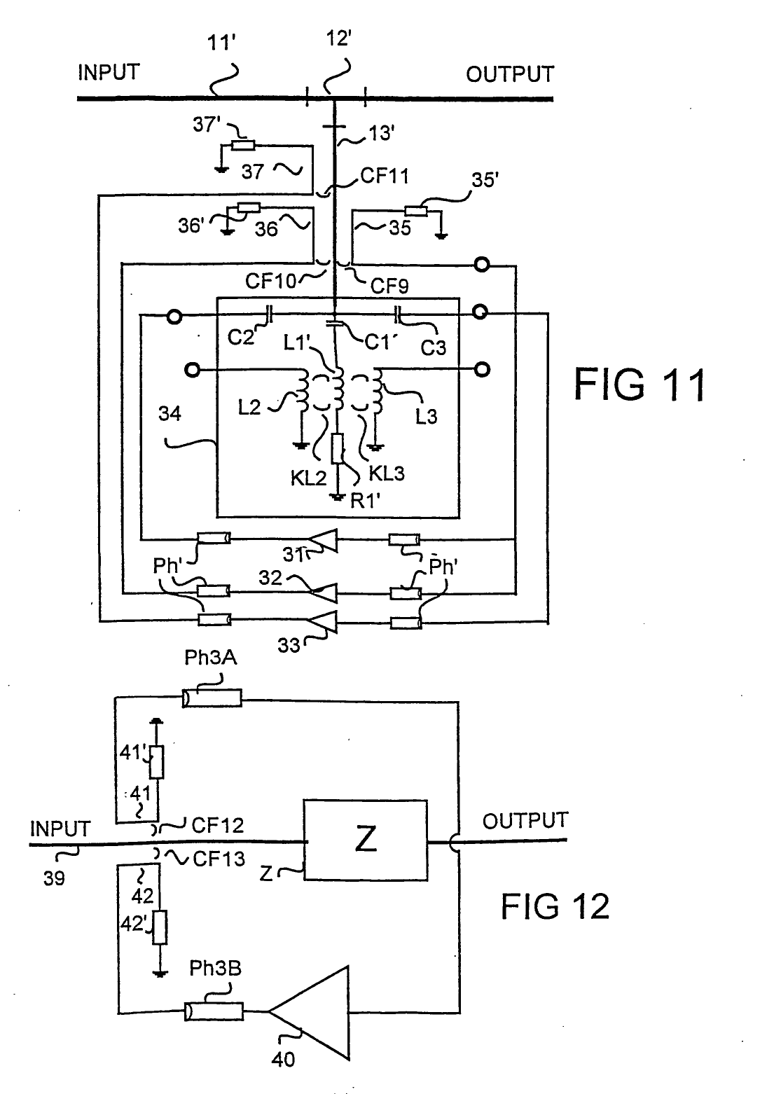

Referring to FIG. 11, which is an examplification of the filter shown in FIG. 3 and in which a particular kind of resonator 34 has been provided as an example of the impedance circuitry Z. Several amplifiers 31, 32, 33 are provided directed to the input side of the main transmission line 11′. Like for all the embodiments the amplifiers 31, 32, 33 have their lines Ph′ connected to all its inputs and outputs functioning as individual phase adjusters, and thus their phase adjusting could be provided by for example changing the length of at least one of its lines.

As illustrated, the input of two of the amplifiers 31, 32 are connected to a coupler 35 having a termination 35′ and its coupling factor CF9. The input of the amplifier 33 is connected to the inside of the resonator 34 and hence to a capacitance coupling C3 to an inside capacitance C1′. It could instead be connected to an inductive coupling L3 having a coupling factor KL3 to an inside inductor L1′. The capacitance C1′, the inductor L1′, and the resistor R1′ are series connected between the line 13′ from the T-connection 12′ and earth. However, it is important that one of the ports of each amplifier is connected to a coupler having an impedance terminator, which is substantially resistive.

Thus, each output of the amplifiers 31 and 32 could be connected to an individual one of the capacitance connection C2, inductance connection L2 having a coupling factor KL2 to the inductance L1′, or one or the other of the couplers 36 or 37, each having a coupling factor CF10 and CF11, respectively, and a termination 36′ and 37′, respectively. The amplifier 33 having its input connected to the inside of the resonator 34 has its output connected to the coupler 37, which is terminated in the way shown and explained in relation to FIGS. 8 to 10. Each coupler is thus provided as an interface between its amplifier and the impedance circuitry, which in this embodiment is represented by the resonator 34. As stated above each coupler has a determined coupling factor between each coupler and the impedance circuitry, i.e. the resonator 34, dependent on the amplifier characteristics and circuitry losses. There are also phase adjusting means for the filter, which could be the lines, the amplifier, the coupler, the impedance circuitry, or some combinations of them.

It is also possible to have an amplifier means that comprises a combination of parallel connected amplifiers 31-33, as in FIG. 11, and an amplifier 14C having at least one, preferably more, outputs and/or inputs, as in FIG. 10.

As in all the embodiments each amplifier has one of its ports (input or output) and the impedance given by the lines, the coupler and its impedance termination matched against each other. The second port of each amplifier (output or input) and the impedance given by the lines and the impedance circuitry are also matched against each other. The matching is provided in dependence of at least one of the features noise, power, and gain. The features disclosed above are due also for all the other embodiments.

The embodiments discussed above are connected parallel to the main transmission line. Below are some embodiments described, which are series connected with the transmission line.

Referring to FIG. 12, which shows another preferred embodiment and shows a basic filter design for a series connection of a filter connected on a main transmission line 39. The filter could be either a band-pass filter, a band-stop filter, a low pass filter or a high pass filter depending on the characteristics of an impedance circuitry Z connected on the line 39. An amplifier 40 has phase adjusting lines Ph3A and Ph3B connected to all its ports such that an impedance is given by the lines, at least one coupler with its termination are matched against each other. The amplifier 40 has its input connected to a coupler 41 and its output connected to a coupler 42. The coupler 41 has a termination 41′, and the coupler 42 has a termination 42′. Both couplers 41 and 42 are provided with a coupling factor CF12 and CF13, respectively, to the input of the main transmission line 39. The phase adjusting line at the input of the amplifier 40 has the reference Ph3A, and at the output the reference PH3B.

The active basic filter could be a low pass filter, a high pass filter, a band pass filter, or a band-stop filter.

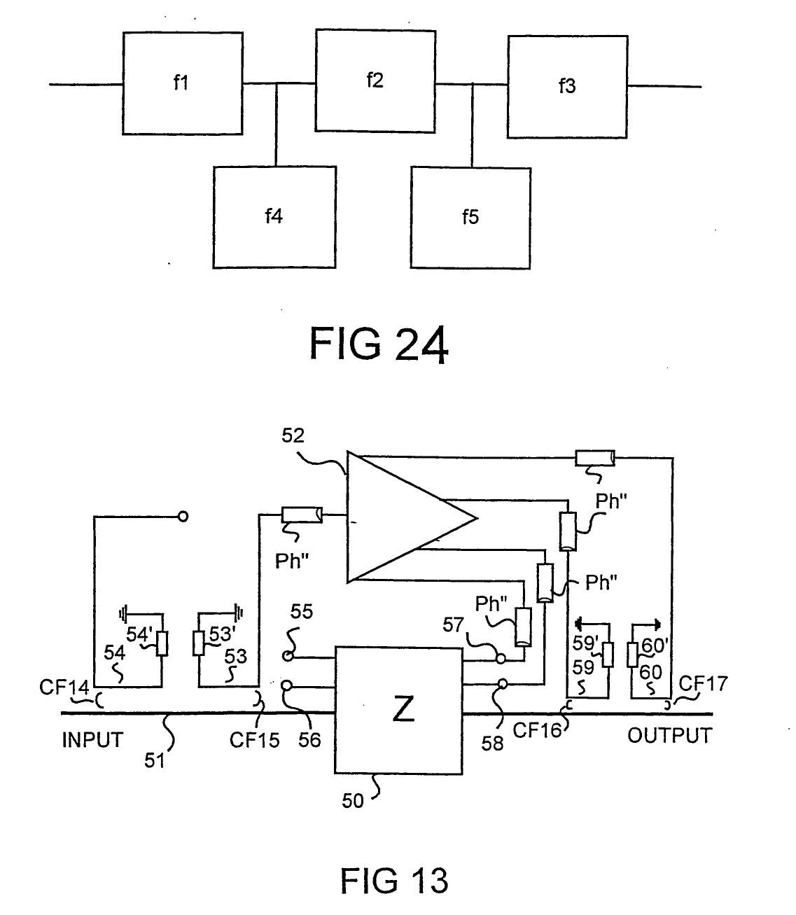

Referring to FIG. 13, which is an exemplification of the serial filter shown in FIG. 12, the filter could be either a band-pass filter, a band-stop filter, a low pass filter, or a high pass filter depending on the characteristics of an impedance circuitry 50 connected on a main transmission line 51. An amplifier 52 has phase adjusting lines Ph″ connected to all its ports such that an impedance given by the lines, at least one coupler with its termination being matched against each other. The amplifier 52 has an input connected to a coupler 53.

However, the input of the amplifier could instead or in addition be connected to another coupler 54 being reverse coupled in relation of the coupler 53, or it could instead or in addition be connected to a capacitance input 55 or an inductive input 56 of the impedance circuitry 50.

The amplifier 52 has four outputs in the embodiment in FIG. 13. If the input of the amplifier 50 is connected to a coupler one output is coupled to for example a capacitance input 57, another output to for example an inductance input 58 of the impedance circuitry 50. Whether the input of the amplifier 52 is connected to a coupler or to the impedance circuitry 50 one of its outputs could be connected to a coupler 59, and yet another to a coupler 60. Each coupler 54, 53, 59, 60 is terminated by a termination 54′, 53′, 59′ and 60′, respectively, which is mainly resistive, and has a coupling factor CFl4, CF15, CF16, and CF17, respectively.

It is to be noted that several amplifiers could be provided instead of an amplifier with multiple outputs. It is also to be noted that only one or only few of the amplifier outputs could be used. The main feature of the filter circuitry shown in FIG. 13 is that at least one of the connections of the amplifier 52 is connected to a coupler having a termination.

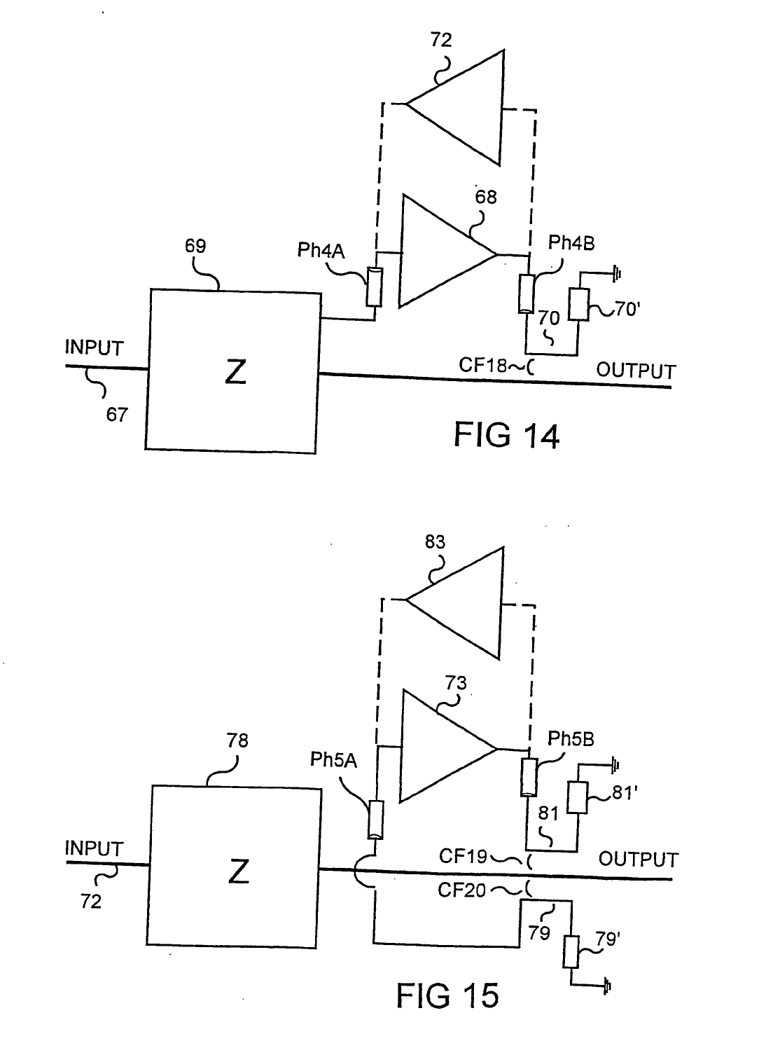

The amplifier could be turned at either direction in the loop. In the FIGS. 14 and 15, which are examplifications of the serial filter shown in FIG. 12, one of the directions is indicated by the amplifier drawn in straight lines, and the other by the amplifier, connected in the circuit in dashed lines. The coupling factor must of course be adapted to the direction of the amplifier in order to provide the same performances in either case.

The embodiment shown in FIG. 15 could also be turned so that the input and output of the main transmission line 72 change place with one another. This is not shown in any Figure, since it is apparent for each person skilled in the art. Of course the amplifier lines could function as phase adjusters, like in all the embodiments described above. Each amplifier and an impedance given by the lines, the coupler(s) and its impedance termination are matched against each other.

FIG. 14 illustrates that the amplifier 68 could be placed at only one side of the impedance circuitry 69. The amplifier 68 has its input through a phase adjuster line Ph4A connected to the inside of the impedance circuitry 69 and has its output through a phase adjuster line Ph4B connected to a coupler 70 having a termination 70′ and a coupling factor CF18 in the embodiment shown. However, the amplifier could as well be turned the other way around. This is illustrated with the amplifier 72 connected with dashed lines.

FIG. 15 illustrates that the amplifier 73 could have both its input and its output through phase adjuster lines Ph5A and Ph5B, respectively, connected to a coupler 79 having a termination 79′ and a coupler 81 having a termination 81′ each. The couplers 79 and 81 are provided on the same side of the impedance circuitry 78 and are in this embodiment shown opposite each other in relation to the main transmission line. Also here could the amplifier be turned the other way around, as illustrated by the reference 83.

Also in the embodiment shown in the FIGS. 14 and 15 the filter could as well be turned so that the input and output of the main transmission line changes place with one another.

For every embodiment discussed above a determined coupling factor is provided between the coupler means and the impedance circuitry in dependence on amplifier characteristics and circuitry losses. The amplifier characteristics to consider are mainly the amplifier gain and the phase. The phase is adjusted on each side of the amplifier by amending the length of the connecting lines Ph5A and Ph5B, respectively, of the input and the output of the amplifier at installation until the filter is functioning optimal.

Below some more examples of filters according to the invention are given.

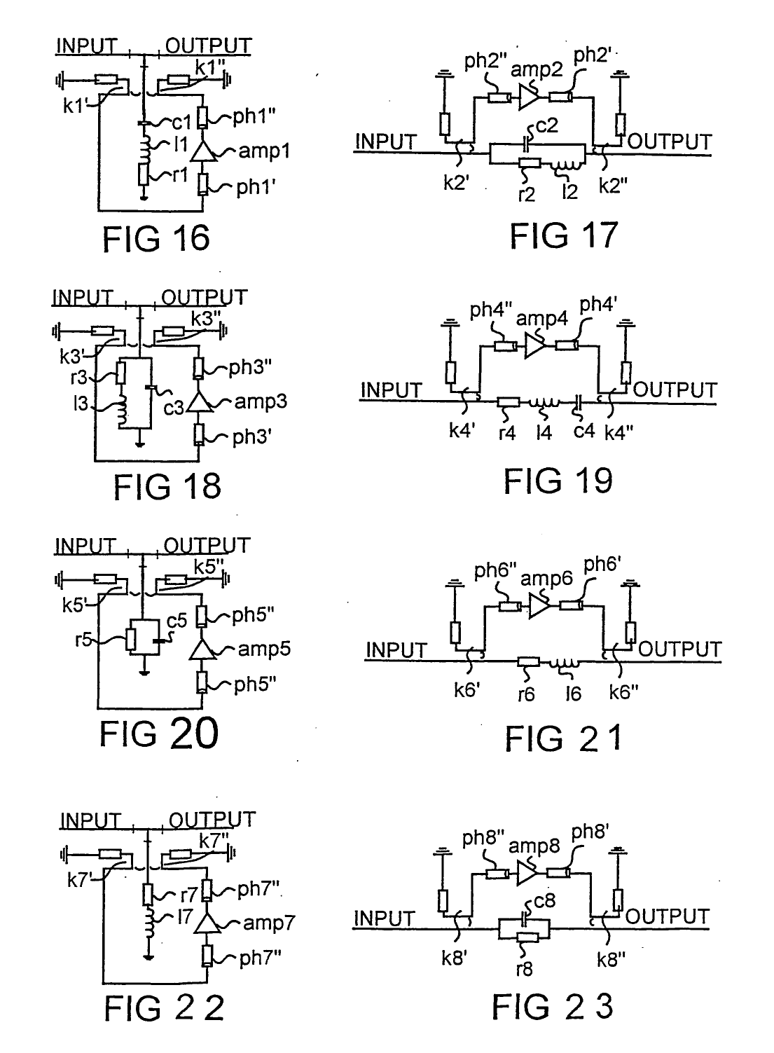

FIGS. 16 and 17 show two kinds of equivalent band-stop circuits. The band-stop circuit in FIG. 16 is provided with two couplers k1′, k1″ provided opposite each other in relation to a transmission line connected to the main transmission line and interconnected by an amplifier amp1 having phase adjuster lines ph1′ and ph1″. The resonator comprises a capacitance c1, an inductance 11 and a resistance r1 in series. The band-stop circuit in FIG. 17 is provided on the main transmission line having one of the two couplers k2′ and k2″ on each side of the resonator. The resonator comprises a capacitor c2 parallel coupled with a resistance r2, and an inductance 12 in series. These circuits also show that the connection between each coupler and the amplifier amp1 and amp2, respectively, comprises a phase adjuster provided by the connection lines ph1′, ph1″ and ph2′, ph2″, respectively.

FIGS. 18 and 19 show two kinds of equivalent band-pass circuits. The band-pass circuit in FIG. 18 is provided with two couplers k3′, k3″ provided opposite each other in relation to a transmission line connected to the main transmission line and interconnected by an amplifier amp3 having the phase adjuster lines ph3′ and ph3″. The resonator comprises a capacitor c3 parallel coupled with a resistance r3 and an inductance 13 in series. The band-pass circuit in FIG. 19 is provided on the main transmission line having one of the two couplers k4′, k4″ on each side of the resonator. The resonator comprises a resistance r4, an inductance 14 and a capacitance c4 in series. These circuits also show that the connection between each coupler and the amplifier amp3 and amp4, respectively, comprises a phase adjuster provided by the connection line ph3′, ph3″ and ph4′, ph4″, respectively.

FIGS. 20 and 21 show two kinds of equivalent low-pass circuits. The low-pass circuit in FIG. 20 is provided with two couplers k5′, k5″ provided opposite each other in relation to a transmission line connected to the main transmission line and interconnected by an amplifier amp5 having the phase adjuster lines ph5′ and ph5″. The reactive component can be complex and comprise a capacitor c5 parallel coupled with a resistance r5. The low-pass circuit in 17 is provided on the main transmission line having one of the two couplers k6′, k6″ on each side of the reactive component. The reactive component comprises a resistance r6 and an inductance 16 in series. These circuits also show that the connection between each coupler and the amplifier amp5 and amp6, respectively, comprises a phase adjuster provided by the connection line ph5′, ph5″ and ph6′, ph6″, respectively.

FIGS. 22 and 23 show two kinds of equivalent high-pass circuits. The high-pass circuit in FIG. 22 is provided with two couplers k7′, k7″ provided opposite each other in relation to a transmission line connected to the main transmission line and interconnected by an amplifier amp7. The reactive component can be complex and comprise a resistance r7 and an inductance 17 in series. The high-pass circuit in FIG. 23 is provided on the main transmission line having one of the two couplers k8′, k8″ on each side of the reactive component. The reactive component comprises a capacitor c8 parallel coupled with a resistance r8. These circuits also show that the connection between each coupler and the amplifier amp7 and amp8, respectively comprises a phase adjuster provided by the connection line ph7′, ph7″ and ph8′, ph8″, respectively.

FIG. 24 shows a combined coupling of several filters. Each filter in the combined coupling being a resonator or reactive component or a more complex filter, with an active feedback loop. As apparent the combination is composed

by both series connected filters f1, f2, and f3 and parallel connected filters f4 and f5. Every block can thus have a filter connected in series with the mainline or parallel to the mainline with or without a connection to ground or a combination of series and parallel connections in the case of a more complex filter. By adding different types of filters in this way filters with improved characteristics of one kind (i.e. band-pass filter or band-stop filter) or of combined kinds (i.e. band-pass+band-stop) can be designed.

Although the invention is described with respect to exemplary embodiments it should be understood that modifications can be made without departing from the scope thereof. Accordingly, the invention should not be considered to be limited to the described embodiments, but defined only by the following claims, which are intended to embrace all equivalents thereof.

1. An active filter for suppressing noise and inter-modulation comprising:
at least one impedance circuitry, such as at least one resonator and/or at least one reactive component,
a feedback loop comprising amplifier means in order to compensate for the power losses provided in the circuitry and making the filter active, and lines connected to the amplifier,
at least one coupler means, each provided as an interface between the amplifier means and the impedance circuitry, at least one of the coupler means being located externally of the impedance circuit; and
an impedance termination for each coupler.

2. An active filter according to claim 1, wherein a determined coupling factor between the coupler means and the impedance circuitry dependent on amplifier characteristics and circuitry losses.

3. An active filter according to claim 2, wherein the determined coupling factor is adapted to obtain an optimum regarding Q-value, noise suppression and inter-modulation suppression.

4. An active filter according to claim 1, wherein phase adjusting means, provided by at least one of the following elements:
the lines,
the amplifier means,
the coupler means,
the impedance circuitry,
a combination of at least two of the elements stated above.

5. An active filter according to claim 1, wherein the impedance termination is either resistive or reactive, or a combination of both.

6. An active filter according to claim 1, wherein the amplifier means comprises at least one, preferably more, parallel connected amplifiers.

7. An active filter according to claim 1, wherein the amplifier means comprises an amplifier having at least one, preferably more, outputs and/or inputs.

8. An active filter according to claim 1, wherein the amplifier means comprises a combination of parallel connected amplifiers and an amplifier having at least one, preferably more, outputs and/or inputs.

9. An active filter according to claim 1, wherein the amplifier means and an impedance given by the lines, the coupler and its impedance termination are matched against each other.

10. An active filter according to claim 9, wherein the matching is provided in dependence of one of the following features:
noise,
power,
gain,
a combination of at least two of the features mentioned above.

11. An active filter according to claim 1, wherein
one port [one of the input(s) or output(s)] of each amplifier means is connected directly to the impedance circuitry; and
another port [one of the output(s) or input(s)] of each amplifier means is connected to the impedance circuitry through the coupler means.

12. An active filter according to claim 11, wherein
a first port (the input/output) of the amplifier means and the impedance given by the lines, the coupler means and its impedance termination are matched against each other; and
a second port (the output/input) of the amplifier means and the impedance given by the lines and the impedance circuitry are matched against each other.

13. An active filter according to claim 12, wherein the matching is provided in dependence of one of the following features:
noise,
power,
gain,
a combination of at least two of the features mentioned above.

14. An active filter according to claim 1, wherein at least one of the input(s) and/or at least one of the output(s) of the amplifier means are connected to the impedance circuitry through an individual one of the coupler means.

15. An active filter according to claim 1, wherein the amplifier means could be connected in either direction in the feedback loop.

16. An active filter according to claim 1, wherein the impedance circuitry is connected either parallel or in series to the main transmission line, or a combination of both.

17. An active filter according to claim 1, wherein the active filter is a low pass filter.

18. An active filter according to claim 1, wherein the active filter is a high pass filter.

19. An active filter according to claim 1, wherein the active filter is a band pass filter.

20. An active filter according to claim 1, wherein the active filter is a band-stop filter.

21. An active filter according to claim 1, wherein the active filter comprises multiple filter elements provided in series, parallel or in combinations of series and parallel combinations.
